(19) United States
(12) Patent Application Publication
(10) Pub. No.: US 2018/0342371 A1
(43) Pub. Date: Nov. 29, 2018

(54) CHARGED PARTICLE BEAM WRITING APPARATUS AND CHARGED PARTICLE BEAM WRITING METHOD

(71) Applicant: NuFlare Technology, Inc., Yokohama-shi (JP)

(72) Inventor: Shunsuke ISAJI, Kouza-gun (JP)

(73) Assignee: NuFlare Technology, Inc., Yokohama-shi (JP)

(21) Appl. No.: 15/962,415

(22) Filed: Apr. 25, 2018

(30) Foreign Application Priority Data
May 29, 2017 (JP) 2017-105816

(51) Int. Cl. H01J 37/304; H01J 37/302; H01J 37/317

(52) U.S. Cl. CPC H01J 37/304; H01J 37/3026; H01J 2237/31793; H01J 2237/30461; H01J 37/3174

(57) ABSTRACT

In one embodiment, a charged particle beam writing apparatus includes a storage unit storing a polynomial and a correction map for correcting deviations of writing positions, a correction processing unit correcting pattern positions in a writing area of a writing target substrate by using the polynomial and correcting the pattern positions in a specific region included in the writing area by using the correction map, and a writing unit writing patterns on a substrate by using a charged particle beam in accordance with the pattern positions corrected by the correction processing unit.

### CROSS REFERENCE TO RELATED APPLICATION

This application is based upon and claims benefit of priority from the Japanese Patent Application No. 2017-105816, filed on May 29, 2017, the entire contents of which are incorporated herein by reference.

### FIELD

The present invention relates to a charged particle beam writing apparatus and a charged particle beam writing method.

### BACKGROUND

An electron beam writing apparatus, which is an example of a charged particle beam writing apparatus, applies an electron beam to a mask substrate including, in sequence, a glass substrate, a chromium film, and a resist film, thus writing a desired pattern. Writing with the electron beam is performed while the mask substrate is grounded. The reason is as follows. If the mask substrate is not grounded, the application of the electron beam to the mask substrate will cause charges to accumulate in the mask substrate, thus generating an electric field. The electric field will bend the trajectory of the electron beam, resulting in a reduction in writing accuracy.

For this reason, a mask cover including a grounding pin is disposed on the mask substrate such that the grounding pin pierces the resist film and comes into contact with the chromium film. Writing with the electron beam is performed on the mask substrate, in which the chromium film is grounded.

The electron beam writing apparatus has important factors including dimensional accuracy and positional accuracy. To correct a coordinate system of the electron beam writing apparatus to an ideal coordinate system, the whole of a surface of a sample, serving as a writing target, is partitioned into mesh cells constituting a mesh or grid and having predetermined dimensions, and a measurement pattern is written at a vertex of each mesh cell. After that, for example, development and etching are performed, and the positions of the written patterns are measured. The coordinate system of the writing apparatus is corrected based on deviations, or errors, of the measured positions from design positions.

To correct the coordinate system, correction using a polynomial (a polynomial correction) and correction using a map are used in combination. The polynomial correction is to correct mask in-plane positional errors by approximating the positional errors using a polynomial function. The positional errors that have been partially corrected by the polynomial correction are corrected using a correction map.

A polynomial function used for polynomial correction is calculated from positional errors of many measurement patterns and thus achieves a higher-averaging effect. In contrast, a correction map, which is intended to correct positional errors at vertices of mesh cells, fails to achieve an averaging effect, resulting in an increase in random errors. The random errors can be reduced by writing measurement patterns on a plurality of mask substrates and averaging correction maps obtained from writing results of the mask substrates. However, such a process results in an increase in cost. In particular, if a plurality of electron beam writing apparatuses are installed, each writing apparatus will write measurement patterns on a plurality of mask substrates, leading to high cost.

### BRIEF DESCRIPTION OF THE DRAWINGS

FIG. 1 is a schematic plan view explaining a conveyance path in an electron beam writing apparatus according to an embodiment of the present invention;

FIG. 2 is a schematic diagram explaining a writing unit of the electron beam writing apparatus according to the embodiment;

FIG. 3A is a plan view of a mask cover;

FIG. 3B is a sectional view taken along the line IIIb-IIIb in FIG. 3(a);

FIG. 3C is a cross-sectional view of the mask cover disposed on a mask substrate;

FIG. 4 is a flowchart explaining a process of correcting mask in-plane positional errors in the embodiment;

FIG. 5A is a diagram illustrating an example of a set of measurements of writing positions of measurement patterns;

FIG. 5B is a diagram illustrating an example of a set of results obtained by correcting positional errors using an approximate polynomial; and

FIG. 6 is a schematic diagram illustrating grounded regions and an ungrounded region.

### DETAILED DESCRIPTION

In one embodiment, a charged particle beam writing apparatus includes a storage unit storing a polynomial and a correction map for correcting deviations of writing positions, a correction processing unit correcting pattern positions in a writing area of a writing target substrate by using the polynomial and correcting the pattern positions in a specific region included in the writing area by using the correction map, and a writing unit writing patterns on a substrate by using a charged particle beam in accordance with the pattern positions corrected by the correction processing unit.

An embodiment of the present invention will be described below with reference to the drawings. In the embodiment, a configuration using an electron beam as an example of a charged particle beam will be described. The charged particle beam is not limited to the electron beam. For example, the charged particle beam may be an ion beam.

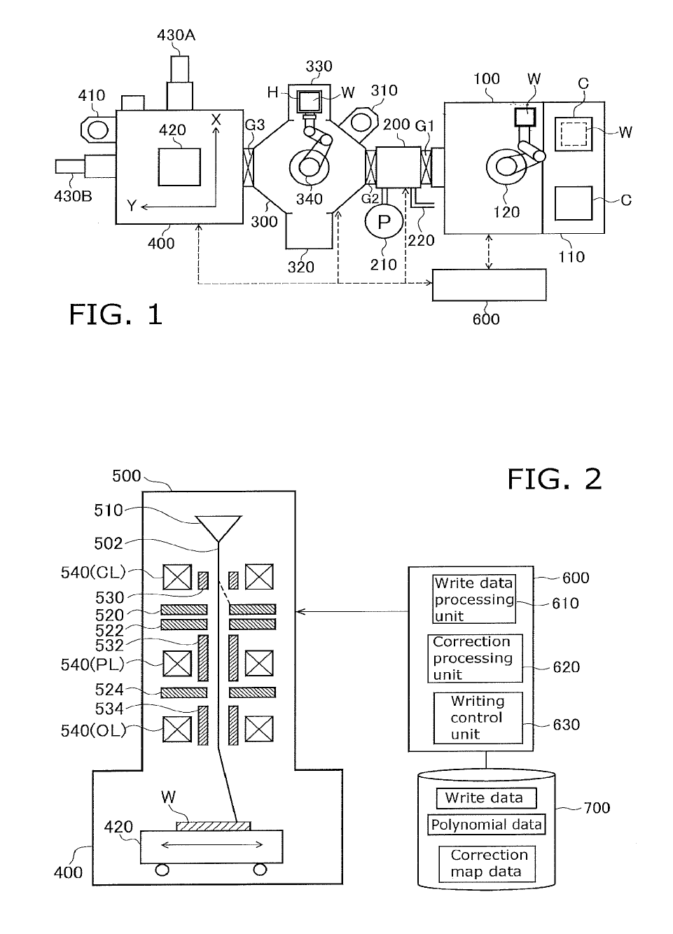

FIG. 1 is a plan view of an electron beam writing apparatus according to the embodiment of the present invention. FIG. 2 is a schematic diagram illustrating a writing chamber (W chamber) 400 and an electron beam optical column 500 included in a writing unit of the electron beam writing apparatus.

As illustrated in FIGS. 1 and 2, the electron beam writing apparatus includes an interface (I/F) unit 100, an input/output (I/O) chamber 200, a robot chamber (R chamber) 300, the W chamber 400, the electron beam optical column 500, a controller 600, a storage device 700, and gate valves G1 to G3. In FIG. 1, the depiction of the electron beam optical column 500 and the storage device 700 is omitted. The R chamber 300 constitutes a transfer chamber.

The I/F unit 100 includes a table 110 on which containers C for receiving a mask substrate W are placed and a transfer robot 120 that transfers the mask substrate W.

The I/O chamber 200 is a load lock chamber for loading or unloading the mask substrate W into/from the R chamber 300 while the R chamber 300 is maintained under vacuum (low pressure). The gate valve G1 is interposed between the I/O chamber 200 and the I/F unit 100. The I/O chamber 200 includes a vacuum pump 210 and a gas supply system 220. The vacuum pump 210, which is, for example, a dry pump or a turbo-molecular pump, evacuates the I/O chamber 200. The gas supply system 220 supplies vent gas (e.g., nitrogen gas or CDA) to the I/O chamber 200 when the I/O chamber 200 is vented to atmospheric pressure.

For evacuation of the I/O chamber 200, the vacuum pump 210 connected to the I/O chamber 200 is used to draw a vacuum within the I/O chamber 200. To return the I/O chamber 200 to atmospheric pressure, the vent gas is supplied from the gas supply system 220 to the I/O chamber 200. Thus, the I/O chamber 200 is returned to atmospheric pressure. When the I/O chamber 200 is evacuated or returned to atmospheric pressure, the gate valves G1 and G2 are closed.

The R chamber 300 includes a vacuum pump 310, an alignment chamber 320, a mask cover receiving chamber 330, and a transfer robot 340. The R chamber 300 is connected to the I/O chamber 200 by the gate valve G2.

The vacuum pump 310 is, for example, a cryopump or a turbo-molecular pump. The vacuum pump 310, which is connected to the R chamber 300, draws a vacuum within the R chamber 300 to maintain high vacuum. The alignment chamber 320 is a chamber for positioning (alignment) of the mask substrate W. The mask cover receiving chamber 330 is a chamber receiving a mask cover H. The mask cover H will be described later. The transfer robot 340 transfers the mask substrate W between the I/O chamber 200, the alignment chamber 320, the mask cover receiving chamber 330, and the W chamber 400.

The W chamber 400 includes a vacuum pump 410, an XY stage 420, and driving mechanisms 430A and 430B. The W chamber 400 is connected to the R chamber 300 by the gate valve G3.

The vacuum pump 410 is, for example, a cryopump or a turbo-molecular pump. The vacuum pump 410, which is connected to the W chamber 400, draws a vacuum within the W chamber 400 to maintain high vacuum. The XY stage 420 is a stage on which the mask substrate W is placed. The driving mechanism 430A drives the XY stage 420 in the X direction. The driving mechanism 430B drives the XY stage 420 in the Y direction.

As illustrated in FIG. 2, the electron beam optical column 500 includes electron beam irradiating means including an electron gun 510, a blanking aperture member 520, a first aperture member 522, a second aperture member 524, a blanking deflector 530, a shaping deflector 532, an objective deflector 534, and lenses 540 (an illumination lens (CL), a projection lens (PL), and an objective lens (OL)), and irradiates the mask substrate W placed on the XY stage 420 with an electron beam. The mask substrate W to be irradiated with the electron beam is covered with the mask cover H, which will be described later. In FIG. 2, the depiction of the mask cover H is omitted.

An electron beam 502 emitted from the electron gun 510 is applied through the illumination lens CL to the entire first aperture member 522 having a rectangular, for example, square aperture. The electron beam 502 is first shaped into a rectangle, for example, a square. The electron beam, serving as a first aperture image, passed through the first aperture member 522 is projected onto the second aperture member 524 through the projection lens PL. The position of the first aperture image on the second aperture member 524 is controlled by the shaping deflector 532, so that the beam can be changed in shape and dimension. The electron beam, serving as a second aperture image, passed through the second aperture member 524 is focused by the objective lens OL. The electron beam is deflected by the objective deflector 534, so that the electron beam is applied to a desired position on the mask substrate W placed on the XY stage 420, which is movably disposed. The controller 600 controls, for example, the application of a deflection voltage to the shaping deflector 532 and the objective deflector 534 and the movement of the XY stage 420. Such a configuration enables the electron beam writing apparatus to serve as a variable-shaped writing apparatus.

The blanking deflector 530 controls the electron beam 502 emitted from the electron gun 510 such that the electron beam passes through the blanking aperture member 520 in a beam ON state and the whole of the electron beam is deflected so as to be interrupted by the blanking aperture member 520 in a beam OFF state. The electron beam passed through the blanking aperture member 520 for a period between the time when the beam OFF state is switched to the beam ON state and the time when the beam ON state is switched to the beam OFF state corresponds to a one-time electron beam shot. A dose of electron beam radiation per shot to the mask substrate W is adjusted depending on irradiation time for each shot.

The controller 600, which is, for example, a computer, has a function of controlling the chambers and the gate valves, for example. The controller 600 includes a write data processing unit 610, a correction processing unit 620, and a writing control unit 630. Functions of these units of the controller 600 may be implemented by hardware or software. If the functions of the units are implemented by software, a program that achieves at least some of the functions of the controller 600 may be stored in a recording medium, and a computer including an electric circuit may read and execute the program. Examples of recording media include, but are not limited to, removable recording media, such as a magnetic disk and an optical disk, and fixed recording media, such as a hard disk drive and a memory.

The controller 600 is connected to the storage device 700, including a hard disk drive, by a bus. The storage device 700 stores write data in which pattern data concerning a plurality of figure patterns to be written is defined. The storage device 700 further stores polynomial data and correction map data. The polynomial data and the correction map data are data to be used for a writing position correction process, which will be described later.

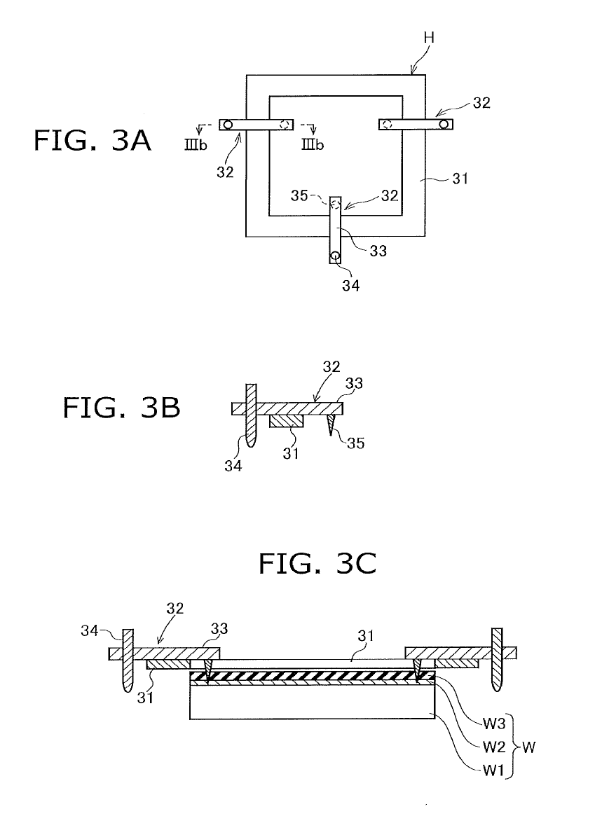

FIG. 3A is a plan view of the mask cover H. FIG. 3B is a sectional view of the mask cover H taken along the line IIIb-IIIb in FIG. 3A. FIG. 3C is a cross-sectional view of the mask cover H disposed on the mask substrate W.

The mask cover H is conductive and includes a picture-frame-shaped frame 31 having a central opening and a plurality of grounding mechanisms 32 arranged on the frame 31. In the present embodiment, a configuration in which the mask cover H includes three grounding mechanisms 32 will be described as an example. The grounding mechanisms 32 are spaced at regular intervals on the frame 31. The size (outer dimensions) of the frame 31 is slightly larger than that of the mask substrate W.

Each grounding mechanism 32 includes a grounding plate 33, which is a plate-shaped conductor, connected to the frame 31. The grounding plate 33 is disposed such that a first end of the grounding plate protrudes outwardly from the frame 31 and a second end thereof protrudes inwardly into the opening of the frame 31. The first end of the grounding plate 33 has a support pin 34 that supports the grounding plate 33 and establishes grounding during writing. The second end of the grounding plate 33 has a grounding pin 35 protruding downward.

The grounding pin 35 is conical and has a bottom surface having a diameter (or width of a portion connected to the grounding plate 33) of approximately 1 mm.

Referring to FIG. 3C, when the mask cover H is set onto the mask substrate W including, in sequence, a glass substrate W1, a light-shielding film (e.g., a chromium film) W2, and a resist film W3, the tip of each grounding pin 35 pierces the resist film W3 under the weight of the mask cover H and comes into contact with the light-shielding film W2, which is a conductor.

While the mask cover H is disposed on the mask substrate W in the above-described manner, writing with the electron beam is performed on the mask substrate W. During this time, the mask cover H is connected to ground (not illustrated). Charges accumulated in the mask substrate W by irradiation with the electron beam are discharged through the mask cover H.

In the mask cover receiving chamber 330, each support pin 34 is supported by a vertically movable support mechanism (not illustrated). This configuration allows the mask cover H to be vertically movably supported. The transfer robot 340 moves the mask substrate W into the mask cover receiving chamber 330 and positions the mask substrate W under the mask cover H. The support mechanism moves the mask cover H downward to set the mask cover H onto the mask substrate W.

The mask cover receiving chamber 330 accommodates a measuring mechanism (not illustrated) for measuring a contact resistance between the mask cover H and the mask substrate W on which the mask cover H is set. The measuring mechanism includes terminals connected to the grounding pins 35 and a measuring circuit for measuring a current or a voltage between the terminals. The terminals are connected to two grounding pins 35, and a current or a voltage between the terminals is measured to determine whether the light-shielding film W2 is connected to the grounding pins 35 and is grounded. The mask substrate W on which the mask cover H is set is carried into the W chamber 400 and is disposed on the XY stage 420.

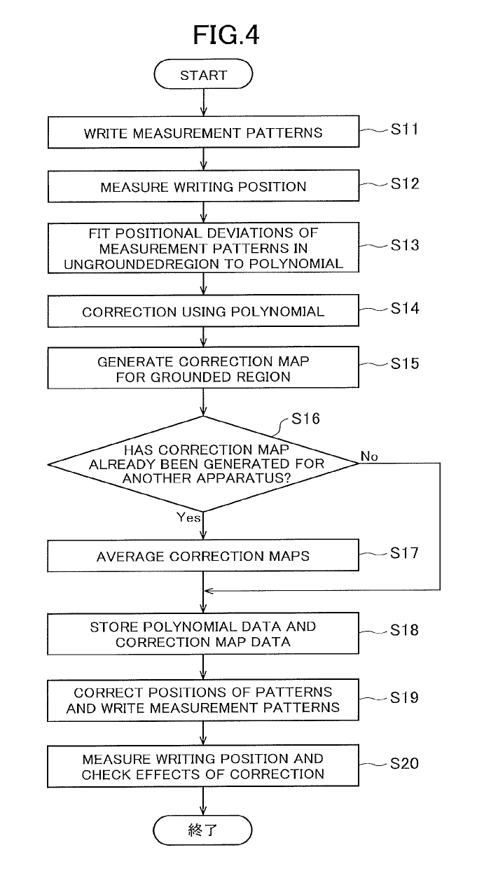

A process of correcting mask in-plane positional errors in the present embodiment will now be described with reference to a flowchart of FIG. 4.

A plurality of measurement patterns (test patterns) are written on a mask substrate (step S11). For example, 37×37 measurement patterns are written over a writing area of the mask substrate such that the patterns are uniformly spaced. After writing, exposure and development are performed, thus forming the measurement patterns. The measurement patterns each have any shape, for example, a cross shape.

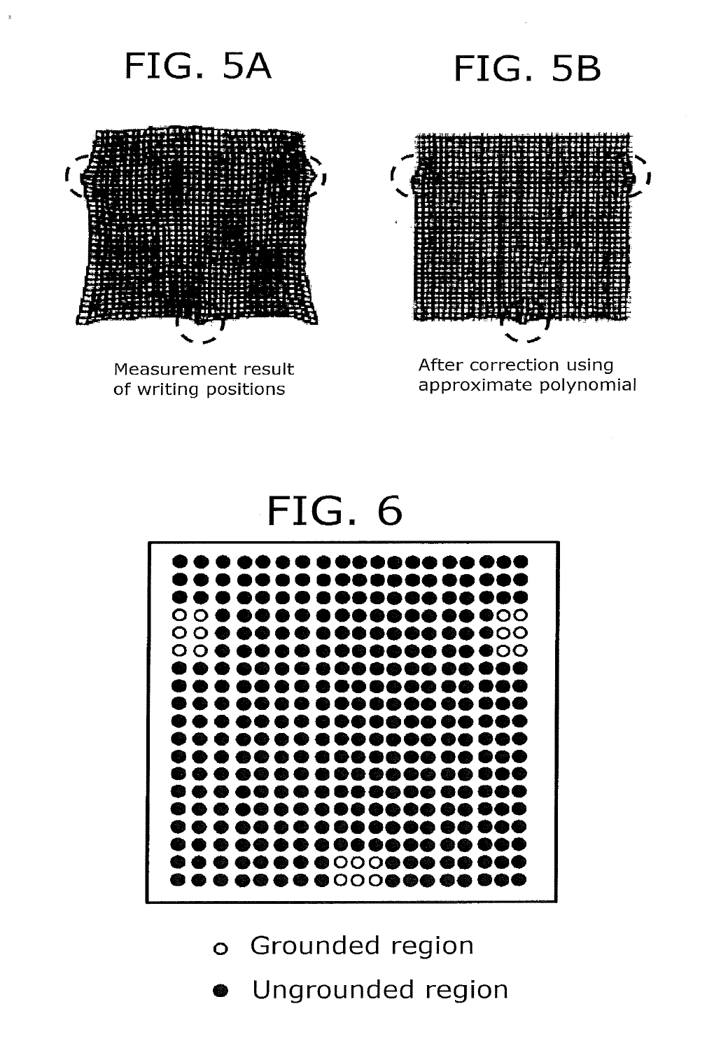

A writing position (formation position) of each measurement pattern is measured (step S12). FIG. 5(a) illustrates an example of a set of measurements of the writing positions of the measurement patterns. A positional deviation, or the difference between a target writing position (design coordinates) and an actual writing position (measurement), of each measurement pattern is obtained.

The positional deviations of the measurement patterns are fit to a polynomial having variables indicating the coordinates (x, y) in a coordinate system of the apparatus (step S13). The polynomial (approximate expression) is a cubic or higher-degree function.

The present inventor has found that, among the measurement patterns formed on the mask substrate, the measurement patterns arranged in proximity to the grounding mechanisms 32, or contacts between the grounding pins 35 and the light-shielding film W2, have writing positions that tend to deviate in a different manner from those of the other measurement patterns (refer to dashed-line circles in FIG. 5A). For this reason, the writing area of the mask substrate is divided into grounded regions, each of which is located in proximity to or within a predetermined distance from the grounding mechanism 32 (grounding pin 35), and an ungrounded region located outside the predetermined distance from the grounding mechanisms 32. The approximate polynomial is calculated from the positional deviations of the measurement patterns in the ungrounded region.

FIG. 6 illustrates an example of arrangement of the grounded regions and the ungrounded region. In FIG. 6, the grounded regions are represented by open circles and the ungrounded region is represented by solid circles. In FIG. 5, the open circles and the solid circles correspond to the target writing positions of the measurement patterns. The approximate polynomial is calculated from the positional deviations of the measurement patterns whose target writing positions are located in the ungrounded region.

The grounded regions are smaller than the ungrounded region. The total area of the grounded regions is preferably 5% or less of the writing area, more preferably 4% or less of the writing area. Since the approximate polynomial is calculated from the positional deviations of many measurement patterns in the large ungrounded region, a higher-averaging effect is achieved.

The positional deviations of the measurements of the writing positions measured in step S12 are corrected using the approximate polynomial obtained in step S13 (step S14). The correction is performed on each of the measurements of the writing positions of all of the measurement patterns including those located in the grounded regions. FIG. 5B illustrates an example of a set of results obtained by correction using a sixth-degree polynomial.

The writing positions of the measurement patterns in the grounded regions are partially corrected using only the approximate polynomial (refer to dashed-line circles in FIG. 5B). For this reason, a correction map is generated to correct the positional deviations (errors), which have been partially corrected using the polynomial, in the grounded regions (step S15).

The correction map is generated only for the grounded regions. In other words, a correction amount is defined for the grounded regions and zero is defined for the ungrounded region in the correction map.

The generated correction map is used to reduce the influence of the grounding mechanisms 32, and can be employed (used) in another electron beam writing apparatus having the same configuration. If a correction map has already been generated for another electron beam writing apparatus having the same configuration (Yes in step S16), the generated correction map and the correction map generated in step S15 may be averaged (step S17).

Data on the polynomial obtained in step S13 and data on the correction map generated in step S15 (or step S17) are stored into the storage device 700 (step S18).

The positions of the patterns are corrected using the polynomial and the correction map stored in the storage device 700, and the measurement patterns are again written (step S19). For example, the correction processing unit 620 corrects the writing positions of all of the measurement patterns by using the polynomial, and further corrects the writing positions in the grounded regions by using the correction map. The writing control unit 630 controls the writing unit to write the measurement patterns at the corrected positions.

After writing, exposure and development are performed, thus forming the measurement patterns. The writing position (formation position) of each measurement pattern is measured to check effects of the correction using the polynomial and the correction map (step S20).

To write an actual pattern on a mask substrate, the write data processing unit 610 reads the write data from the storage device 700 and performs multi-stage data conversion on the write data, thus generating shot data specific to the apparatus. In the shot data, for example, the shape, size, position, and shot time of a shot are defined. The correction processing unit 620 corrects the position of a figure pattern defined in the write data by reference to the polynomial and the correction map. Consequently, the position of the pattern in the write data can be corrected before the write data is developed into shot data. The writing control unit 630 controls the writing unit in accordance with the shot data.

As described above, according to the present embodiment, the writing positions are corrected with the polynomial obtained from the positional deviations in the ungrounded region, which accounts for most of the writing area of the mask substrate. Thus, writing is less susceptible to random errors. The grounded regions to be subjected to correction with the map are limited regions, which are extremely narrower than the ungrounded region. The influence of variations in positional deviation on the grounded regions is very small.

For the correction map, a correction map obtained for another apparatus having the same configuration can be used. In addition, the correction map obtained for the apparatus and a correction map obtained for another apparatus can be averaged, thus enhancing the accuracy of the correction map because of data accumulation.

According to the present embodiment, it is unnecessary to write measurement patterns on each of a plurality of mask substrates in each of a plurality of electron beam writing apparatuses. Writing positional accuracy can be efficiently improved.

In the above-described embodiment, the measurement patterns are written at the regular intervals in the grounded regions and the ungrounded region, and the writing positions of the measurement patterns are measured. In the ungrounded region, the distance between the patterns whose writing positions are to be measured may be increased to reduce the number of targets to be measured. The reason is as follows. Since the ungrounded region is larger than the grounded regions, a polynomial can be adequately calculated if the number of targets to be measured is reduced. Consequently, the time it takes to measure the writing positions can be shortened.

Furthermore, the distance between the measurement patterns to be written in the ungrounded region may be longer than those in the grounded regions. In other words, the density of the patterns in the ungrounded region may be lower than that in the grounded regions. Thus, the time it takes to write the measurement patterns can be shortened.

The above-described embodiment has focused on the grounding mechanisms 32. The writing area is divided into the grounded regions (specific regions) and the ungrounded region (nonspecific region). The polynomial is calculated from the positional deviations in the ungrounded region, and the correction map for the grounded regions is generated. The division into the specific regions and the nonspecific region is not limited to the division into the grounded regions and the ungrounded region. For example, since the mask substrate is supported at three support points in the W chamber 400, the writing area may be divided into regions (specific regions) in proximity to the support points and the other region (nonspecific region). Furthermore, the writing area may be divided into corner regions (specific regions) of the mask substrate and the other region (nonspecific region).

Although the writing apparatus for writing with a single electron beam has been described in the above embodiment, the apparatus may be a multi-beam writing apparatus.

While certain embodiments have been described, these embodiments have been presented by way of example only, and are not intended to limit the scope of the inventions. Indeed, the novel methods and systems described herein may be embodied in a variety of other forms, furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A charged particle beam writing apparatus comprising:
a storage unit storing a polynomial and a correction map for correcting deviations of writing positions;
a correction processing unit correcting pattern positions in a writing area of a writing target substrate by using the polynomial and correcting the pattern positions in a specific region included in the writing area by using the correction map; and
a writing unit writing patterns on a substrate by using a charged particle beam in accordance with the pattern positions corrected by the correction processing unit.

2. The apparatus according to claim 1,
wherein the writing unit writes the patterns on the substrate while a mask cover including a frame having a central opening, at least one grounding plate attached to the frame and having an end protruding inwardly into the opening of the frame, and a grounding pin protruding downward from the end of the grounding plate is disposed on the substrate such that a tip of the grounding pin is in contact with the substrate, and
wherein the specific region is a region located within a predetermined distance from the contact of the grounding pin.

3. The apparatus according to claim 2, wherein the at least one grounding plate attached to the frame includes a plurality of grounding plates.

4. The apparatus according to claim 1, wherein the specific region has an area less than or equal to 5% of the writing area.

5. The apparatus according to claim 1, wherein the correction map contains a correction amount defined for the specific region and zero defined for a region other than the specific region.

6. The apparatus according to claim 1,
wherein the substrate is supported at three support points, and
wherein the specific region includes regions located within a predetermined distance from the support points.

7. A charged particle beam writing method comprising:
writing a plurality of test patterns over a writing area of a first substrate through a writing unit of a charged particle beam writing apparatus;
measuring a writing position of each of the plurality of test patterns to obtain a positional deviation from design coordinates of each test pattern;
dividing the writing area into a specific region and a nonspecific region;
calculating an approximate polynomial by fitting positional deviations of the test patterns within the nonspecific region to a coordinate system of the apparatus;
generating a correction map for measurements of the writing positions of the test patterns within the specific region, the correction map being used to correct positional deviations to be partially corrected using the approximate polynomial;
reading write data, in which pattern data concerning a plurality of figure patterns is defined, from a storage device;
correcting positions of the plurality of figure patterns using the approximate polynomial;
correcting the positions of the figure patterns within the specific region using the correction map; and
writing, in accordance with the corrected positions, the figure patterns on a second substrate through the writing unit.

8. The method according to claim 7,
wherein the writing unit writes the patterns on the substrate while a mask cover including a frame having a central opening, at least one grounding plate attached to the frame and having an end protruding inwardly into the opening of the frame, and a grounding pin protruding downward from the end of the grounding plate is disposed on the substrate such that a tip of the grounding pin is in contact with the substrate, and
wherein the specific region is a region located within a predetermined distance from the contact of the grounding pin.

9. The method according to claim 8, wherein the at least one grounding plate attached to the frame includes a plurality of grounding plates.

10. The method according to claim 7,
wherein the calculating the approximate polynomial includes calculating an approximate polynomial for a first charged particle beam writing apparatus and the generating the correction map includes generating a correction map for the first charged particle beam writing apparatus,
wherein the calculating the approximate polynomial includes calculating an approximate polynomial for a second charged particle beam writing apparatus, and
wherein the second charged particle beam writing apparatus uses the correction map for the first charged particle beam writing apparatus.

11. The method according to claim 7, wherein the specific region has an area less than or equal to 5% of the writing area.

12. The method according to claim 7,
wherein the first substrate is supported at three support points in the writing unit, and
wherein the specific region includes regions located within a predetermined distance from the support points.
